(19) United States
(12) Patent Application Publication
(10) Pub. No.: US 2026/0101486 A1
(43) Pub. Date: Apr. 9, 2026

(54) HEATSINK-INTEGRATED CERAMIC SUBSTRATE AND METHOD FOR PRODUCING SAME

(71) Applicant: AMOGREENTECH CO., LTD., Tongjin-eup Gimpo-si, Gyeonggi-do (KR)

(72) Inventor: Jihyung LEE, Tongjin-eup Gimpo-si (KR)

(73) Assignee: AMOGREENTECH CO., LTD., Tongjin-eup Gimpo-si, Gyeonggi-do (KR)

(21) Appl. No.: 19/111,830

(22) PCT Filed: Sep. 7, 2023
(86) PCT No.: PCT/KR2023/013401

§ 371 Date: Mar. 14, 2025

(30) Foreign Application Priority Data
Sep. 23, 2022 (KR) 10-2022-0120661

(51) Int. Cl. H05K 7/20

(52) U.S. Cl. CPC H05K 7/209

(57) ABSTRACT

A heat sink-integrated power module substrate according to an embodiment of the present disclosure may include a ceramic heat sink including a flat portion and a plurality of protrusions that are formed on a bottom surface of the flat portion to protrude at intervals and that contact liquid coolant, and an electrode pattern bonded to a top surface of the ceramic heat sink and configured to allow a semiconductor chip to be bonded thereto. Here, since the ceramic heat sink is formed of a ceramic material effective in heat dissipation, heat dissipation performance may be enhanced.

### TECHNICAL FIELD

The present disclosure relates generally to a heat sink-integrated power module substrate and a method of manufacturing the heat sink-integrated power module substrate, and more particularly to a heat sink-integrated power module substrate in which an electrode pattern or a ceramic substrate is bonded to a ceramic heat sink and a method of manufacturing the heat sink-integrated power module substrate.

### BACKGROUND ART

An electric vehicle requires an inverter that converts a Direct Current (DC) voltage provided by a high-voltage battery into a 3-phase Alternating Current (AC) voltage required to drive a motor.

A power module for controlling the high voltage of a driving battery to a state suitable for the motor and supplying the controlled voltage is assembled with the inverter. The power module includes a semiconductor chip for power conversion, and the semiconductor chip generates high-temperature heat due to a high voltage and high current operation. When such heat persists, a problem arises in that the semiconductor chip is degraded and the performance of the power module is deteriorated. In order to solve this problem, a heat sink is bonded to at least one surface of a ceramic or metal substrate to prevent the degradation of semiconductor chips caused by heat.

Generally, a heat sink is made of a metal material having high thermal conductivity, such as copper or aluminum, and even such a metal heat sink has a limitation in heat dissipation, thus rapidly decreasing cooling efficiency and causing warping to lead to failures when heat exceeding the limitation is generated. Further, a problem arises in that warping or the like attributable to heat occurs even in a substrate on which a semiconductor chip is mounted, thus degrading characteristics.

The matters described in the above background art are intended to aid in understanding the background of the disclosure and may include aspects that are not part of the disclosed prior art.

### SUMMARY OF INVENTION

### Technical Problem

The present disclosure has been made keeping in mind the above problems, and an object of the present disclosure is to provide a heat sink-integrated power module substrate, which is configured to effectively dissipate heat generated in semiconductor chips, and a method of manufacturing the heat sink-integrated power module substrate.

### Solution to Problem

To achieve the above object, a heat sink-integrated power module substrate according to an embodiment of the present disclosure may include a ceramic heat sink including a flat portion and a plurality of protrusions that are formed on a bottom surface of the flat portion to protrude at intervals and that contact liquid coolant, and an electrode pattern bonded to a top surface of the ceramic heat sink and configured to allow a semiconductor chip to be bonded thereto. Here, the electrode pattern may be formed to have a thickness of 0.6 mm or more and 9.0 mm or less.

The ceramic heat sink may be formed of any one of AlN, Si₃N₄, Zirconia Toughed Alumina (ZTA), Al₂O₃, or SiC.

In addition, the heat sink-integrated power module substrate according to an embodiment of the present disclosure may further include a brazing filler layer disposed between the top surface of the ceramic heat sink and a bottom surface of the electrode pattern and configured to bond the ceramic heat sink and the electrode pattern, wherein the brazing filler layer may be formed of a material including at least one of Ag, Cu, AgCu and AgCuTi.

The plurality of protrusions may be arranged in an external coolant circulation unit, and liquid coolant circulating through the coolant circulation unit may perform heat exchange with the plurality of protrusions.

The electrode pattern may be formed of any one of Cu, Al, or a Cu alloy. Further, the electrode pattern may include a peripheral surface that is formed to be inclined. Here, the peripheral surface may include a protrusion length that increases in a direction closer to the ceramic heat sink. Also, the peripheral surface may be formed to be depressed toward the ceramic heat sink. Meanwhile, the peripheral surface may be formed in a stepped shape, and respective stages forming a step may have different protrusion lengths.

A heat sink-integrated power module substrate according to another embodiment of the present disclosure may include a ceramic heat sink including a flat portion and a plurality of protrusions that are formed on a bottom surface of the flat portion to protrude at intervals and that contact liquid coolant, and a ceramic substrate including a ceramic base, an upper metal layer on a top surface of the ceramic base, and a lower metal layer on a bottom surface of the ceramic base, the ceramic substrate being bonded to a top surface of the ceramic heat sink. Here, the ceramic heat sink may be formed of any one of AlN, Si₃N₄, Zirconia Toughed Alumina (ZTA), Al₂O₃, or SiC.

In addition, the heat sink-integrated power module substrate according to the other embodiment of the present disclosure may further include a brazing filler layer disposed between a top surface of the ceramic heat sink and a bottom surface of the lower metal layer and configured to bond the ceramic heat sink and the lower metal layer, wherein the brazing filler layer may be formed of a material including at least one of Ag, Cu, AgCu and AgCuTi.

The heat sink-integrated power module substrate according to a further embodiment of the present disclosure may further include an electrode pattern bonded to a top surface of the upper metal layer of the ceramic substrate and configured to allow a semiconductor chip to be boned thereto.

A method of manufacturing a heat sink-integrated power module substrate, according to an embodiment of the present disclosure may include preparing a ceramic heat sink, bonding an electrode layer to a top surface of the ceramic heat sink, and forming an electrode pattern configured to allow a semiconductor chip to be mounted thereon by etching the electrode layer.

Here, the bonding of the electrode layer may include disposing a brazing filler layer between the top surface of the ceramic heat sink and a bottom surface of the electrode layer, and bonding the electrode layer and the ceramic heat sink by melting the brazing filler layer.

The disposing of the brazing filler layer may include disposing a brazing filler layer formed of a material including at least one of Ag, AgCu and AgCuTi using any one method of plating, paste application, or foil attachment.

In the preparing of the ceramic heat sink, the ceramic heat sink may be manufactured using any one method of injection molding or die casting.

The forming of the electrode pattern may include forming a photoresist pattern on a top surface of the electrode layer, etching the electrode layer by using the photoresist pattern as an etching mask, and etching the brazing filler layer that is exposed as the electrode layer is etched until a top surface of the ceramic heat sink is exposed.

### Advantageous Effects of Invention

In the present disclosure, a ceramic heat sink is formed of a ceramic material effective in heat dissipation, so that the coefficient of thermal expansion is lower than that of a heat sink formed of a metal material, and thus warping hardly occurs even in a high-temperature environment, and heat dissipation performance can be enhanced.

Further, in the present disclosure, even if high-temperature heat is generated from a semiconductor chip, continuously circulating liquid coolant directly contacts a ceramic heat sink to cool the ceramic heat sink, thereby maximizing heat dissipation effect.

Furthermore, in the present disclosure, an electrode pattern is formed of any one of Cu, Al, or a Cu alloy and is formed at a relatively large thickness of 0.6 mm or more and 9.0 mm or less, so that electrical conductivity and thermal conductivity are excellent, and thus the present disclosure is applicable to a power module for high-power power conversion.

Furthermore, in the present disclosure, an electrode pattern is formed such that the thickness of an edge region thereof is reduced in a direction closer to a ceramic heat sink, thus alleviating thermal stress by dispersing energy in the edge region, and ensuring reliability by maintaining bonding strength.

Furthermore, in the present disclosure, a ceramic substrate is integrally bonded to a ceramic heat sink, and thus warping of the ceramic substrate can be effectively suppressed by the ceramic heat sink.

### BRIEF DESCRIPTION OF DRAWINGS

FIG. 1 is a top perspective view illustrating a heat sink-integrated power module substrate according to an embodiment of the present disclosure.

FIG. 2 is a bottom perspective view illustrating a heat sink-integrated power module substrate according to an embodiment of the present disclosure.

FIG. 3 is a front view illustrating a heat sink-integrated power module substrate according to an embodiment of the present disclosure.

FIG. 4 is a bottom perspective view illustrating a modified example of a plurality of protrusions in a heat sink-integrated power module substrate according to an embodiment of the present disclosure.

FIG. 5 is a front view illustrating a modified example of an electrode pattern in a heat sink-integrated power module substrate according to an embodiment of the present disclosure.

FIG. 6 is a conceptual view illustrating a configuration in which a heat sink-integrated power module substrate is mounted on a coolant circulation unit and a circulation driving unit is connected to the coolant circulation unit according to an embodiment of the present disclosure.

FIG. 7 is a perspective view illustrating a heat sink-integrated power module substrate according to another embodiment of the present disclosure.

FIG. 8 is a front view illustrating a heat sink-integrated power module substrate according to the other embodiment of the present disclosure.

FIG. 9 is a front view illustrating a heat sink-integrated power module substrate according to a further embodiment of the present disclosure.

FIG. 10 is a flowchart illustrating a method of manufacturing a heat sink-integrated power module substrate according to an embodiment of the present disclosure.

FIG. 11 is a view for describing the step of forming an electrode pattern in the method of manufacturing a heat sink-integrated power module substrate according to an embodiment of the present disclosure.

### DESCRIPTION OF EMBODIMENTS

Hereinafter, exemplary embodiments of the present disclosure will be described in detail with reference to the attached drawings.

The embodiments are provided to more completely describe the present disclosure to those skilled in the art, the following embodiments may be modified in various different forms, and the scope of the present disclosure is limited to the following embodiments. Rather, these embodiments are provided to further enrich and complete the present disclosure and to fully convey the spirit of the present disclosure.

Terms used in the present specification are intended to describe specific embodiments and are not intended to limit the present disclosure. In addition, in the present specification, singular forms may include plural forms unless the context clearly indicates otherwise.

In the description of embodiments, when each layer (film), region, pattern, or structure is described as being formed “on” or “under” a substrate, each layer (film), region, pad, or pattern, the terms “on” and “under” encompass “directly” formed structures or “indirectly” formed structures with the interposition of another layer. In addition, the reference for “on” or “under” with respect to each layer is, in principle, based on the drawings.

Drawings are merely intended to help understanding of the spirit of the present disclosure, and should not be construed as limiting the scope of the present disclosure. Furthermore, the relative thickness, length, or size depicted in the drawings may be exaggerated for the convenience and clarity of description.

Hereinafter, embodiments of the present disclosure will be described in detail with reference to the attached drawings.

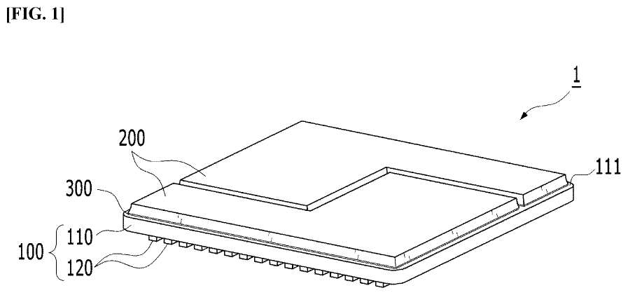

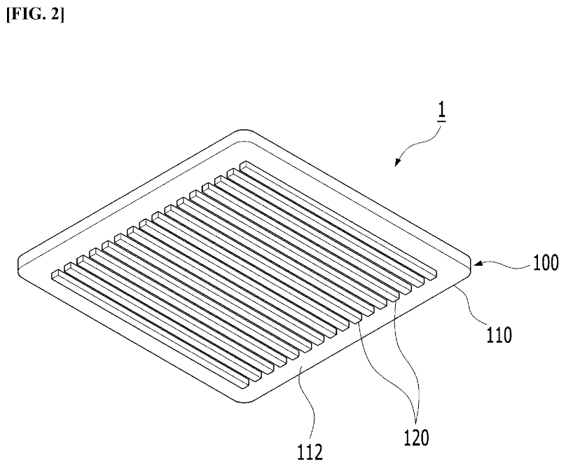

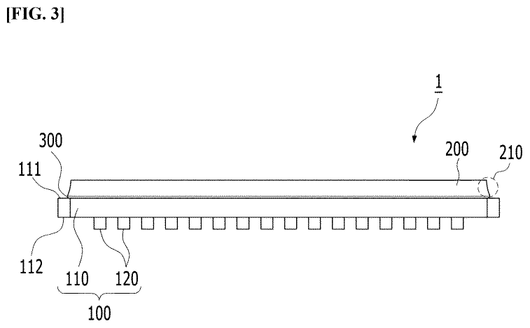

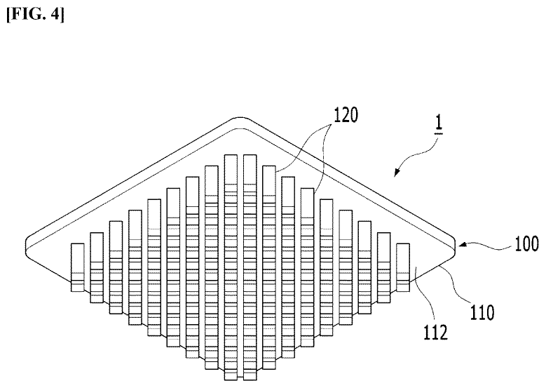

FIG. 1 is a top perspective view illustrating a heat sink-integrated power module substrate according to an embodiment of the present disclosure, FIG. 2 is a bottom perspective view illustrating a heat sink-integrated power module substrate according to an embodiment of the present disclosure, FIG. 3 is a front view illustrating a heat sink-integrated power module substrate according to an embodiment of the present disclosure, and FIG. 4 is a bottom perspective view illustrating a modified example of a plurality of protrusions in a heat sink-integrated power module substrate according to an embodiment of the present disclosure.

As illustrated in FIGS. 1 to 3, a heat sink-integrated power module substrate 1 according to an embodiment of the present disclosure may include a ceramic heat sink 100 and electrode patterns 200.

The ceramic heat sink 100 may be formed of any one of AlN, Si₃N₄, Zirconia Toughed Alumina (ZTA), Al₂O₃, and SiC. In case that the ceramic heat sink 100 is formed of a metal material such as Cu, the coefficient of thermal expansion of Cu is 17 ppm/K, and thus warping caused by thermal expansion occurs when the ceramic heat sink is applied to a power module in which heat of 200° C. or higher is generated, thus decreasing a heat dissipation function, and resulting in a short circuit at the time of connecting the ceramic heat sink to a lead frame or the like through a wire.

On the other hand, in case that the ceramic heat sink 100 is formed of any one of AlN, Si₃N₄, Zirconia Toughed Alumina (ZTA), Al₂O₃, and SiC, warping hardly occurs even in a high-temperature environment of 600° C. or higher, and thus heat dissipation performance may be enhanced. In addition, since AlN has a thermal conductivity of 150 W/m·K or more and Si₃N₄ has a thermal conductivity of 80 W/m·K or more, they may be effective in heat dissipation when used for the heat sink.

The ceramic heat sink 100 may include a flat portion 110 and a plurality of protrusions 120. The flat portion 110 may be a portion, in which the electrode patterns 200 are bonded to a top surface 111 thereof, to directly contact the electrode patterns 200, and may be provided in the form of a flat panel having a large area so as to facilitate heat transfer. The flat portion 110 may be formed to have a thickness of 0.6 mm or more and 9.0 mm or less. In this way, in the case where the flat portion 110 is formed at a relatively large thickness of 0.6 mm or more and 9.0 mm or less, a heat dissipation area increases to allowing heat to evenly spread, and thereby the flat portion may be effective in heat dissipation.

The plurality of protrusions 120 may be formed on a bottom surface 112 of the flat portion 110 to protrude at intervals. The ceramic heat sink 100 may be provided in a slit type in which a plurality of bar-shaped protrusions 120 are horizontally arranged at intervals. Alternatively, as illustrated in FIG. 4, the ceramic heat sink 100 may be of a pin fin type, in which the plurality of protrusions 120 having a rhombus-shaped cross-section are formed in pin shapes or in which the plurality of protrusions 120 are provided in various pin shapes such as a cylindrical shape, a polygonal prism shape, a teardrop shape, or a diamond shape. The shape, number, and arrangement form of the plurality of protrusions 120 may be variously changed depending on the results of previous simulations during design. The plurality of protrusions 120 may be provided to directly contact liquid coolant. Since the liquid coolant moves between the plurality of protrusions 120, the flow rate, cooling efficiency, or the like of the liquid coolant may be easily controlled as the shape, number, and arrangement form of the plurality of protrusions 120 are changed.

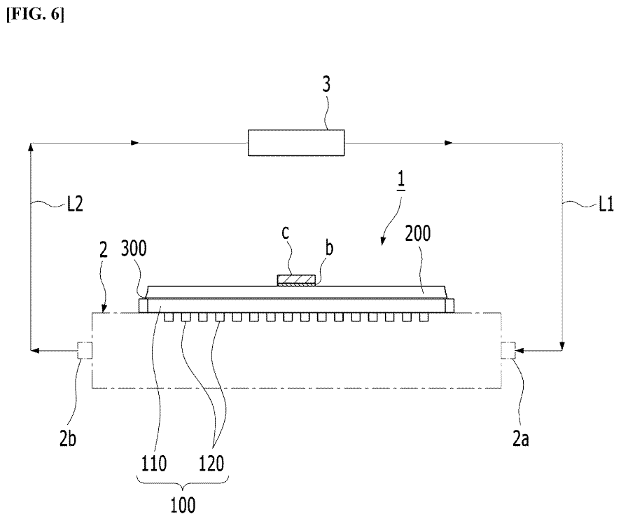

Each electrode pattern 200 may be bonded to the top surface 111 of the ceramic heat sink 100, and may be configured to allow a semiconductor chip c (see FIG. 6) to be mounted thereon. Here, the semiconductor chip c may be SiC, GaN, Si, LED, VCSEL or the like. Such a semiconductor chip c may be bonded to the top surface of the electrode pattern 200 by a bonding layer b containing solder or Ag paste. Although not illustrated in detail, a plurality of semiconductor chips c may be bonded to the electrode pattern 200, and may be electrically connected through wire bonding, flip-chip bonding, or the like.

The electrode pattern 200 may be provided at a thickness of 0.6 mm or more and 9.0 mm or less. In the case where the electrode pattern 200 to which the semiconductor chip c is bonded is formed to have a large thickness in this way, high voltage and high current may be conducted. In case of railway vehicles, power conversion for high power is performed compared to general vehicles, so the electrode pattern 200 needs to have high electrical conductivity, and also needs to have high thermal conductivity for heat dissipation. Because the heat sink-integrated power module substrate 1 according to the embodiment of the present disclosure is configured such that the electrode pattern 200 is formed of any one of Cu, Al, or a Cu alloy and is formed at a relatively large thickness of 0.6 mm or more and 9.0 mm or less, there are advantages in that electrical conductivity and thermal conductivity are excellent to enable application to a power module for high-power power conversion.

The electrode pattern 200 may be bonded to the top surface 111 of the ceramic heat sink 100 via a brazing filler layer 300. The brazing filler layer 300 may be disposed between the top surface 111 of the ceramic heat sink 100 and the bottom surface of the electrode pattern 200, and may integrally bond the ceramic heat sink 100 to the electrode pattern 200 at brazing temperature. The brazing may be performed at a temperature of 450° C. or higher, desirably, a temperature ranging from 780° C. to 900° C. The brazing filler layer 300 may be formed of a material containing at least one of Ag, Cu, AgCu and AgCuTi, and the thickness thereof may range from about 20 μm to 100 μm. Ag, AgCu and AgCuTi may have high thermal conductivity to function to enhance bonding strength while facilitating heat transfer between the ceramic heat sink 100 and the electrode pattern 200, thereby improving heat dissipation efficiency.

The electrode pattern 200 may be formed to have an inclined peripheral surface 210. Here, the peripheral surface 210 may be formed to have a protrusion length that increases in a direction closer to the ceramic heat sink 100. Also, the peripheral surface 210 may be formed to be depressed toward the ceramic heat sink 100. Because an edge region in which stress is concentrated, such as a corner and a boundary, is vulnerable to thermal shock, cracks may occur under rapid temperature changes. Therefore, when the peripheral surface 210 is formed such that the protrusion length thereof increases as it is closer to the ceramic heat sink 100, the thickness of the edge region is minimized and energy in the edge region is dispersed, thereby alleviating thermal stress.

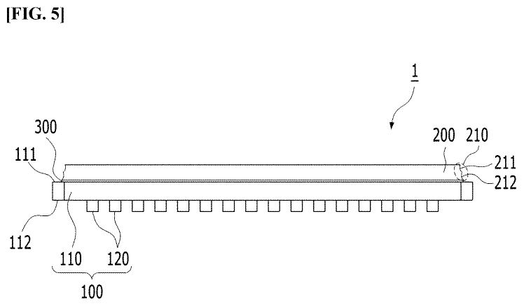

FIG. 5 is a front view illustrating a modified example of an electrode pattern in a heat sink-integrated power module substrate according to an embodiment of the present disclosure.

Referring to FIG. 5, in a heat sink-integrated power module substrate 1 according to an embodiment of the present disclosure, a peripheral surface 210 may be provided in a stepped shape. Here, the stepped shape refers to a shape forming multiple stages. Respective stages 211 and 212 forming the step on the peripheral surface 210 may be formed to have different protrusion lengths. In detail, the respective stages 211 and 212 forming the step on the peripheral surface 210 may be formed to have protrusion lengths increased as the stages are closer to a ceramic heat sink 100. That is, the lower stage 212 may be formed to protrude beyond the upper stage 211. In this way, in case that the thickness of the edge region decreases, energy in the edge region is dispersed, and thus thermal stress is alleviated and robustness to thermal shock increases.

FIG. 6 is a conceptual view illustrating a configuration in which a heat sink-integrated power module substrate is mounted on a coolant circulation unit and a circulation driving unit is connected to the coolant circulation unit according to an embodiment of the present disclosure.

As illustrated in FIG. 6, according to an embodiment of the present disclosure, a plurality of protrusions 120 in a heat sink-integrated power module substrate 1 may be arranged in a coolant circulation unit 2. The coolant circulation unit 2 may be provided with an inlet 2a through which liquid coolant flows in, an outlet 2b through which the liquid coolant is discharged, and an internal flow path (not illustrated) extending from the inlet 2a to the outlet 2b. Here, the liquid coolant flowing into the coolant circulation unit 2 through the inlet 2a of the coolant circulation unit 2 may be discharged through the outlet 2b via the internal flow path. Since the shape and size of the internal flow path that is a path through which the liquid coolant is moved between the inlet 2a and the outlet 2b may be designed and modified in various manners, detailed description of the internal flow path itself of the coolant circulation unit 2 will be omitted.

A circulation driving unit 3 may be connected to the coolant circulation unit 2, and may circulate the liquid coolant using the driving force of a pump (not illustrated). Here, the inlet 2a of the coolant circulation unit 2 may be connected to the circulation driving unit 3 through a first circulation line L1, and the outlet 2b of the coolant circulation unit 2 may be connected to the circulation driving unit 3 through a second circulation line L2. That is, the circulation driving unit 3 may continuously circulate the liquid coolant along a circulation path including the first circulation line L1, the coolant circulation unit 2, and the second circulation line L2. Here, the liquid coolant may be, but is not limited to, deionized water, and may be implemented using liquid nitrogen, alcohol, or other solvents as needed.

The liquid coolant supplied from the circulation driving unit 3 may flow into the inlet 2a of the coolant circulation unit 2 through the first circulation line L1, move along the internal flow path formed in the coolant circulation unit 2, and be discharged through the outlet 2b, after which the liquid coolant may move back to the circulation driving unit 3 through the second circulation line L2. Although not illustrated in detail, the circulation driving unit 3 may include a heat exchanger (not illustrated). The heat exchanger of the circulation driving unit 3 may decrease the temperature of the liquid coolant, the temperature of which has increased while passing through the internal flow path of the coolant circulation unit 2, and the circulation driving unit 3 may supply the liquid coolant, the temperature of which has decreased by the heat exchanger, back to the first circulation line L1 using the driving force of the pump.

In this way, the coolant circulation unit 2 may be provided such that the liquid coolant supplied from the circulation driving unit 3 is continuously circulated. Here, the plurality of protrusions 120 may be arranged in the internal flow path of the coolant circulation unit 2, and may directly contact the liquid coolant continuously circulating along the internal flow path to perform heat exchange. That is, the plurality of protrusions 120 have a water-cooled heat dissipation structure that allows direct cooling by the continuously circulating liquid coolant to be performed.

Even if high-temperature heat is generated from a semiconductor chip c mounted on an electrode pattern 200, the plurality of protrusions 120 are compulsorily cooled by continuously circulating liquid coolant, and thus the semiconductor chip c may be maintained at a constant temperature to prevent the degradation thereof. That is, even if high-temperature heat of about 100° C. or higher is generated in the semiconductor chip, the temperature of the liquid coolant that circulates along the internal flow path of the coolant circulation unit 2 is about 25° C., and thus heat transferred to the plurality of protrusions 120 may be rapidly cooled.

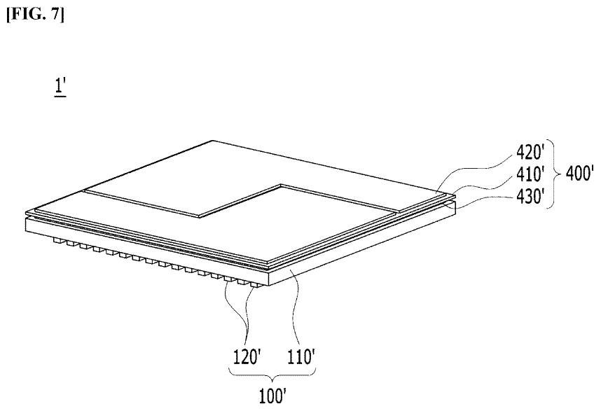

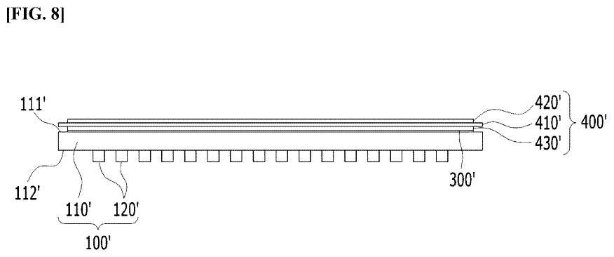

Hereinafter, a heat sink-integrated power module substrate according to another embodiment of the present disclosure will be described with reference to FIGS. 7 and 8. For convenience of description, description of the same components as those in the embodiment illustrated in FIGS. 1 to 6 will be omitted, and description will be made based on the difference therebetween.

FIG. 7 is a perspective view illustrating a heat sink-integrated power module substrate according to another embodiment of the present disclosure, and FIG. 8 is a front view illustrating the heat sink-integrated power module substrate according to the other embodiment of the present disclosure.

As illustrated in FIGS. 7 and 8, a heat sink-integrated power module substrate 1′ according to the other embodiment of the present disclosure may include a ceramic heat sink 100′ and a ceramic substrate 400′.

The ceramic substrate 400′ may be bonded to a top surface 111′ of the ceramic heat sink 100′. The ceramic substrate 400′ may be an Active Metal Brazing (AMB) substrate or a Direct Bonded Copper (DBC) substrate. The AMB substrate or the DBC substrate may be a substrate in which metal is directly bonded to a ceramic base. In the ceramic substrate 400′, an upper metal layer 420′ may be provided on the top surface of a ceramic base 410′ and a lower metal layer 430′ may be provided on the bottom surface of the ceramic base 410′ so as to enhance the efficiency of dissipating heat generated from a semiconductor chip. Here, the thickness of the ceramic base 410′ may be 0.32 mm, and the thickness of each of the upper and lower metal layers 420′ and 430′ may be 0.3 mm.

The ceramic base 410′ may be made of an oxide-based or nitride-based ceramic material. For example, the ceramic base 410′ may be, but is not limited to, any one of alumina (Al₂O₃), AlN, SiN, Si₃N₄, or Zirconia Toughened Alumina (ZTA).

The upper metal layer 420′ may be arranged on the top surface of the ceramic base 410′, and may be provided in the shape of a circuit pattern. For example, the upper metal layer 420′ may be provided as a Cu sheet or an Al sheet and brazed to the top surface of the ceramic base 410′, and may then be formed into an electrode pattern on which a semiconductor chip is mounted and an electrode pattern on which a driving element is mounted, through etching.

The lower metal layer 430′ may be arranged on the bottom surface of the ceramic base 410′. For example, the lower metal layer 430′ may be provided as a Cu sheet or an Al sheet and brazed to the bottom surface of the ceramic base 410′. The lower metal layer 430′ may be formed as a flat panel so that heat transfer is facilitated by increasing a bonding area with the ceramic heat sink 100′. In this way, when the volume of the lower metal layer 430′ formed as the flat panel is compared with the volume of the upper metal layer 420′ formed into the electrode pattern, a volume difference therebetween is large, and thus a phenomenon in which the lower metal layer is warped in case of heat generation from the semiconductor chip may occur.

On the other hand, in the heat sink-integrated power module substrate 1′ according to the other embodiment of the present disclosure, warping of the ceramic substrate 400′ may be suppressed by the ceramic heat sink 100′ because the ceramic substrate 400′ is bonded to the ceramic heat sink 100′. Since the ceramic heat sink 100′ is formed of any one of ceramic materials such as AlN, Si₃N₄, Zirconia Toughed Alumina (ZTA), Al₂O₃, or SiC, warping hardly occurs even in a high-temperature environment of 600° C. or higher. Therefore, the ceramic heat sink 100′ may not only prevent its warping in a high-temperature environment during a brazing process with the ceramic substrate 400′, but also effectively suppress the warping of the ceramic substrate 400′ even after being bonded to the ceramic substrate 400′.

The lower metal layer 430′ of the ceramic substrate 400′ may be bonded to the top surface 111′ of the ceramic heat sink 100′ via a brazing filler layer 300′. The brazing filler layer 300′ may be disposed between the top surface 111′ of the ceramic heat sink 100′ and the bottom surface of the lower metal layer 430′, and may integrally bond the ceramic heat sink 100′ to the lower metal layer 430′ at brazing temperature. The brazing may be performed at a temperature of 450° C. or higher, desirably, a temperature ranging from 780° C. to 900° C. The brazing filler layer 300′ may be formed of a material containing at least one of Ag, Cu, AgCu and AgCuTi, and the thickness thereof may range from about 20 μm to 100 μm. Ag, AgCu and AgCuTi have high thermal conductivity to function to enhance bonding strength while facilitating heat transfer between the ceramic heat sink 100′ and the lower metal layer 430′, thereby improving heat dissipation efficiency.

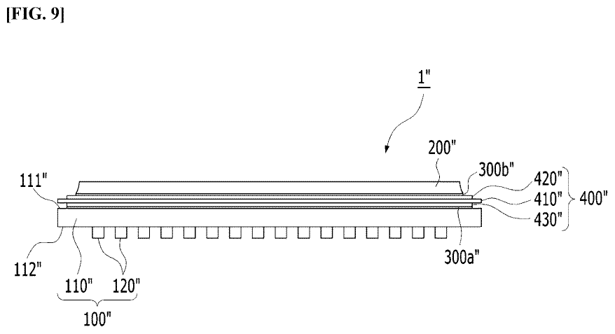

FIG. 9 is a front view illustrating a heat sink-integrated power module substrate according to a further embodiment of the present disclosure.

As illustrated in FIG. 9, in a heat sink-integrated power module substrate 1″ according to the further embodiment of the present disclosure, a lower metal layer 430″ of a ceramic substrate 400″ may be bonded to the top surface of a ceramic heat sink 100″ via a brazing filler layer 300a″, and an electrode pattern 200″ may be bonded to the top surface of an upper metal layer 420″ of the ceramic substrate 400″.

In detail, the electrode pattern 200″ may be formed in the shape of a pattern corresponding to the upper metal layer 420″ of the ceramic substrate 400″, and may be bonded to the top surface of the upper metal layer 420″ via a brazing filler layer 300b″. Such an electrode pattern 200″ may be formed in the shape of a pattern to which a semiconductor chip c (see FIG. 6) is to be bonded. The electrode pattern 200″ may be provided at a thickness of 0.6 mm or more and 9.0 mm or less. In the case where the electrode pattern 200″ to which the semiconductor chip c is bonded is formed to have a large thickness in this way, high voltage and high current may be conducted. In case of railway vehicles, power conversion for high power is performed compared to general vehicles, so the electrode pattern 200″ needs to have high electrical conductivity, and also needs to have high thermal conductivity for heat dissipation. Because the heat sink-integrated power module substrate 1″ according to the further embodiment of the present disclosure is configured such that the electrode pattern 200″ bonded to the top surface of the ceramic substrate 400″ is formed of any one of Cu, Al, or a Cu alloy and is formed at a relatively large thickness of 0.6 mm or more and 9.0 mm or less, electrical conductivity and thermal conductivity are excellent to enable application to a power module for high-power power conversion.

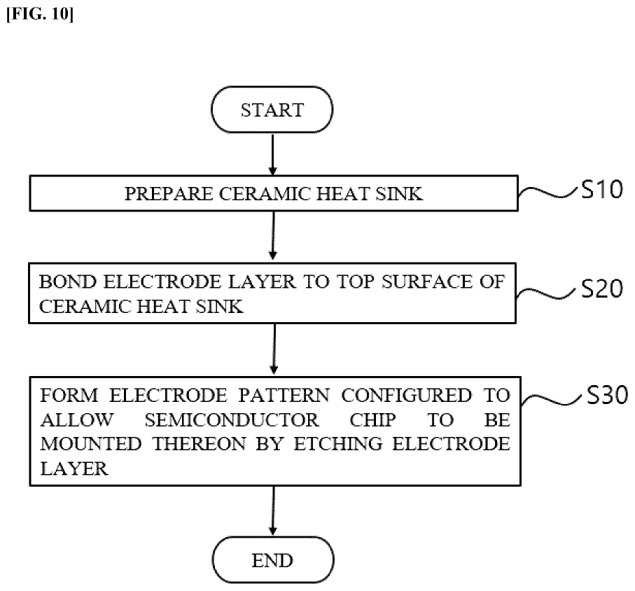

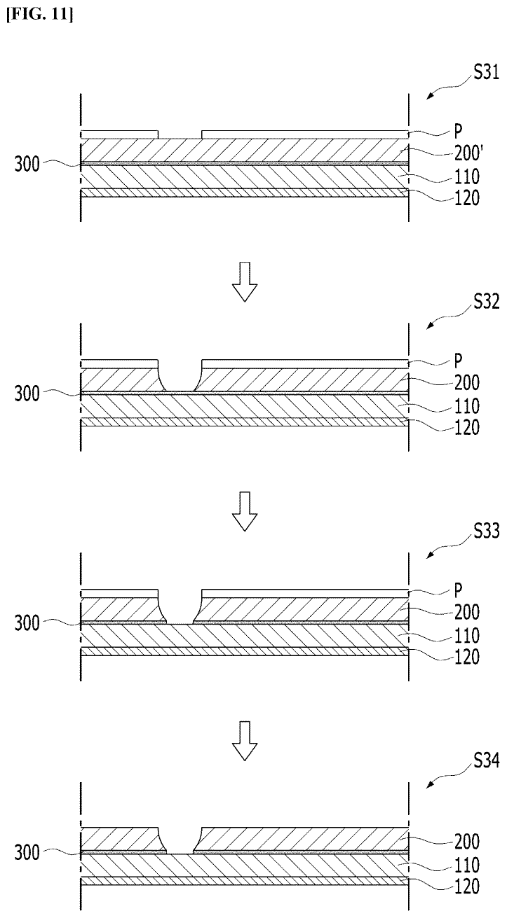

FIG. 10 is a flowchart illustrating a method of manufacturing a heat sink-integrated power module substrate according to an embodiment of the present disclosure, and FIG. 11 is a view for describing the step of forming an electrode pattern in the method of manufacturing a heat sink-integrated power module substrate according to an embodiment of the present disclosure.

As illustrated in FIGS. 10 and 11, the method of manufacturing a heat sink-integrated power module substrate according to an embodiment of the present disclosure may include step S10 of preparing a ceramic heat sink 100, step S20 of bonding an electrode layer 200′ to a top surface 111 of the ceramic heat sink 100, and step S30 of forming an electrode pattern 200 configured to allow a semiconductor chip to be mounted thereon by etching the electrode layer 200′.

In step S10 of preparing the ceramic heat sink 100, the ceramic heat sink 100 may be formed of any one of AlN, Si₃N₄, Zirconia Toughed Alumina (ZTA), Al₂O₃, or SiC. When the ceramic heat sink 100 is formed of any one of AlN, Si₃N₄, Zirconia Toughed Alumina (ZTA), Al₂O₃, or SiC, warping hardly occurs even in a high-temperature environment of 600° C. or higher, thus enhancing heat dissipation performance. In addition, since AlN has a thermal conductivity of 150 W/m·K or more and Si₃N4 has a thermal conductivity of 80 W/m·K or more, they may be effective in heat dissipation when used for the heat sink.

The ceramic heat sink 100 may be manufactured by any one method of injection molding (ceramic injection molding) or die casting. Injection molding is a construction method of injecting a heated ceramic material into a cavity in a closed mold and cooling the ceramic material within the mold, thus forming a molded product corresponding to the mold cavity. Further, the die-casting construction method is a method of injecting a ceramic material into a mold and then obtaining a casting identical to the mold, thus enabling the mass production of molded products with complex shapes. After the injection molding or die casting, the ceramic heat sink 100 may be manufactured through a heat treatment process and, in addition, the ceramic heat sink 100 may also be formed using a construction method such as extrusion, cutting processing, or press processing.

In step S10 of preparing the ceramic heat sink 100, the ceramic heat sink 100 may be provided with a flat portion 110 and a plurality of protrusions 120. The flat portion 110 may be a portion in which the top surface 111 directly contacts the electrode pattern 200, and may be provided in the form of a flat panel having a large area so as to facilitate heat transfer. The plurality of protrusions 120 may be formed on a bottom surface 112 of the flat portion 110 to protrude at intervals. The plurality of protrusions 120 may be arranged in an external coolant circulation unit 2 and provided to directly contact liquid coolant that circulates through the coolant circulation unit 2. The ceramic heat sink 100 may be provided in a slit type in which a plurality of bar-shaped protrusions 120 are horizontally arranged at intervals. Alternatively, the ceramic heat sink 100 may be of a pin fin type, in which the plurality of protrusions 120 having a rhombus-shaped cross-section are formed in pin shapes or in which the plurality of protrusions 120 are provided in various pin shapes such as a cylindrical shape, a polygonal prism shape, a teardrop shape, or a diamond shape.

Step S20 of bonding the electrode layer 200′ to the top surface 111 of the ceramic heat sink 100 may include the step of disposing a brazing filler layer 300 between the top surface 111 of the ceramic heat sink 100 and the bottom surface of the electrode layer 200′, and the step of bonding the electrode layer 200′ and the ceramic heat sink 100 by melting the brazing filler layer 300.

In the step of disposing the brazing filler layer 300, the brazing filler layer 300 may be disposed using any one method of plating, paste application, or foil attachment. The brazing filler layer 300 may be formed of a material containing at least one of Ag, AgCu and AgCuTi, and the thickness thereof may range from about 20 □ to 100 □, but the present disclosure is not limited thereto. The step of bonding the electrode layer 200′ and the ceramic heat sink 100 by melting the brazing filler layer 300 may be performed at a temperature of 450° C. or higher, desirably, a temperature ranging from 780 to 900° C., wherein upper weighting or pressurizing may be performed to enhance bonding strength.

FIG. 11 is a view for describing the step of forming the electrode pattern in the method of manufacturing a heat sink-integrated power module substrate according to an embodiment of the present disclosure.

Referring to FIG. 11, step S30 of forming the electrode pattern 200 configured to allow a semiconductor chip to be mounted thereon by etching the electrode layer 200′ may include step S31 of forming a photoresist pattern p on the top surface of the electrode layer 200′, step S32 of etching the electrode layer 200′ by using the photoresist pattern p as an etching mask, and step S33 of etching the brazing filler layer 300 exposed as the electrode layer 200′ is etched until the top surface of the ceramic heat sink 100 is exposed.

In step S31 of forming the photoresist pattern p, the photoresist pattern p may be formed by performing a photolithography process on the electrode layer 200′. Although not illustrated in detail, the photolithography process may include forming a photoresist layer, and thereafter forming the photoresist pattern p by performing an exposure and development process on the photoresist layer.

After step S31 of forming the photoresist pattern p, step S32 of etching the electrode layer 200′ by using the photoresist pattern p as the etching mask may be performed. In this case, as the electrode layer 200′ is etched, the brazing filler layer 300 may be exposed through a portion in which the electrode layer 200′ is etched. In order to remove the exposed portion, step S33 of etching the exposed brazing filler layer 300 until the top surface of the ceramic heat sink 100 is exposed may be performed. Here, a material formed through a reaction between the ceramic heat sink 100 and the brazing filler layer 300 may also be etched. For example, when the ceramic heat sink 100 is a nitride-based material such as AlN or Si₃N₄, the ceramic heat sink 100 may react with Ti in the brazing filler layer 300 to form TiN, and thus TiN may also be etched. Thereafter, by performing step S34 of removing the photoresist pattern p through dry etching or wet etching, electrode patterns 200 separated from each other may be formed in accordance with a pre-designed circuit pattern.

Although not illustrated in the drawings, the step of removing a portion of the electrode layer 200′ within a range of 50% to 90% of the total thickness of the electrode layer 200′ through mechanical processing may be further included between step S20 of bonding the electrode layer 200′ and step S30 of forming the electrode patterns 200. That is, in case that each electrode pattern 200 is formed to have a large thickness, forming the electrode pattern using only the etching process is problematic in that etching time is lengthened, and thus productivity may be decreased. Therefore, in the case where a portion of the electrode layer 200′ is removed within the range of 50% to 90% of the total thickness according to a predefined pattern using a mechanical processing method, such as press processing or cutting processing before the etching process, the thickness of the electrode layer 200′ to be etched is reduced during the etching step, thus significantly shortening the time required for the etching process. For example, when a pattern groove having a thickness of 7 mm is formed in advance even if the electrode layer 200′ is very thick, approximately 10 mm, the thickness of the portion of the electrode layer 200′ corresponding to the pattern groove is reduced to 3 mm, with the result that etching time is reduced.

The above-described heat sink-integrated power module substrate according to an embodiment of the present disclosure may be applied to a power module to ensure both multiple and large-scale connections of semiconductor chips and heat dissipation effect, and may also contribute to small-size implementation to further enhance the performance of the power module.

The above-described heat sink-integrated power module substrate according to embodiments of the present disclosure may be applied to various module components used for high power, in addition to the power module.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the scope of the claims and equivalents thereof should be construed as being included in the scope of the present disclosure.

1. A heat sink-integrated power module substrate, comprising:
a ceramic heat sink including a flat portion and a plurality of protrusions that are formed on a bottom surface of the flat portion to protrude at intervals and that contact liquid coolant; and
an electrode pattern bonded to a top surface of the ceramic heat sink and configured to allow a semiconductor chip to be bonded thereto.

2. The heat sink-integrated power module substrate of claim 1, wherein the electrode pattern is formed to have a thickness of 0.6 mm or more and 9.0 mm or less.

3. The heat sink-integrated power module substrate of claim 1, wherein the ceramic heat sink is formed of any one of AlN, Si₃N₄, Zirconia Toughed Alumina (ZTA), Al₂O₃, or SiC.

4. The heat sink-integrated power module substrate of claim 1, further comprising:
a brazing filler layer disposed between the top surface of the ceramic heat sink and a bottom surface of the electrode pattern and configured to bond the ceramic heat sink and the electrode pattern,
wherein the brazing filler layer is formed of a material including at least one of Ag, Cu, AgCu and AgCuTi.

5. The heat sink-integrated power module substrate of claim 1, wherein:
the plurality of protrusions are arranged in an external coolant circulation unit, and
liquid coolant circulating through the coolant circulation unit performs heat exchange with the plurality of protrusions.

6. The heat sink-integrated power module substrate of claim 1, wherein the electrode pattern is formed of any one of Cu, Al, or a Cu alloy.

7. The heat sink-integrated power module substrate of claim 1, wherein the electrode pattern includes a peripheral surface that is formed to be inclined.

8. The heat sink-integrated power module substrate of claim 7, wherein the peripheral surface includes a protrusion length that increases in a direction closer to the ceramic heat sink.

9. The heat sink-integrated power module substrate of claim 7, wherein the peripheral surface is formed to be depressed toward the ceramic heat sink.

10. The heat sink-integrated power module substrate of claim 7, wherein the peripheral surface is formed in a stepped shape, and respective stages forming a step have different protrusion lengths.

11. A heat sink-integrated power module substrate, comprising:
a ceramic heat sink including a flat portion and a plurality of protrusions that are formed on a bottom surface of the flat portion to protrude at intervals and that contact liquid coolant; and
a ceramic substrate including a ceramic base, an upper metal layer on a top surface of the ceramic base, and a lower metal layer on a bottom surface of the ceramic base, the ceramic substrate being bonded to a top surface of the ceramic heat sink.

12. The heat sink-integrated power module substrate of claim 11, wherein the ceramic heat sink is formed of any one of AlN, Si₃N₄, Zirconia Toughed Alumina (ZTA), Al₂O₃, or SiC.

13. The heat sink-integrated power module substrate of claim 11, further comprising:
a brazing filler layer disposed between a top surface of the ceramic heat sink and a bottom surface of the lower metal layer and configured to bond the ceramic heat sink and the lower metal layer,
wherein the brazing filler layer is formed of a material including at least one of Ag, Cu, AgCu and AgCuTi.

14. The heat sink-integrated power module substrate of claim 11, further comprising:
an electrode pattern bonded to a top surface of the upper metal layer of the ceramic substrate and configured to allow a semiconductor chip to be boned thereto.

15. A method of manufacturing a heat sink-integrated power module substrate, comprising:
preparing a ceramic heat sink;
bonding an electrode layer to a top surface of the ceramic heat sink; and
forming an electrode pattern configured to allow a semiconductor chip to be mounted thereon by etching the electrode layer.

16. The method of claim 15, wherein the bonding of the electrode layer comprises:
disposing a brazing filler layer between the top surface of the ceramic heat sink and a bottom surface of the electrode layer; and
bonding the electrode layer and the ceramic heat sink by melting the brazing filler layer.

17. The method of claim 16, wherein the disposing of the brazing filler layer comprises:
disposing a brazing filler layer formed of a material including at least one of Ag, AgCu and AgCuTi using any one method of plating, paste application, or foil attachment.

18. The method of claim 15, wherein:
in the preparing of the ceramic heat sink,
the ceramic heat sink is manufactured using any one method of injection molding or die casting.

19. The method of claim 16, wherein the forming of the electrode pattern comprises:
forming a photoresist pattern on a top surface of the electrode layer;
etching the electrode layer by using the photoresist pattern as an etching mask; and
etching the brazing filler layer that is exposed as the electrode layer is etched until a top surface of the ceramic heat sink is exposed.
